(19) United States
(12) Patent Application Publication
(10) Pub. No.: US 2011/0074021 A1
(43) Pub. Date: Mar. 31, 2011

(54) DEVICE MOUNTING BOARD, AND SEMICONDUCTOR MODULE

(75) Inventors: Mayumi NAKASATO, Ogaki-shi (JP); Kouichi Saitou, Ogaki-shi (JP); Tetsuya Yamamoto, Hashima-shi (JP)

(73) Assignee: SANYO ELECTRIC CO., LTD.

(21) Appl. No.: 12/895,417

(22) Filed: Sep. 30, 2010

(30) Foreign Application Priority Data
Sep. 30, 2009 (JP) 2009-228104

(51) Int. Cl. H01L 23/48; H05K 1/11

(52) U.S. Cl. 257/737; 174/261; 257/E23.021

(57) ABSTRACT

A device mounting board includes an insulating resin layer, a wiring layer provided on one of main surfaces of the insulating resin layer, and bump electrodes connected electrically to the wiring layer and protruding on a side of the insulating resin layer from the wiring layer. A semiconductor module is formed by having the bump electrodes connected to a semiconductor device. A recess is provided in the top face of each bump electrode. The recess communicates with an opening provided on a side surface of the bump electrode.

### CROSS-REFERENCE TO RELATED APPLICATIONS

This application is based upon and claims the benefit of priority from the prior Japanese Patent Application No. 2009-228104, filed on Sep. 30, 2009, the entire contents of which are incorporated herein by reference.

### BACKGROUND OF THE INVENTION

1. Field of the Invention

The present invention relates to a device mounting board, a semiconductor module and a mobile apparatus.

2. Description of the Related Art

A known method of surface-mounting a semiconductor device is flip-chip mounting in which solder bumps are formed on electrodes of the semiconductor device and the solder bumps are connected to an electrode pad of a printed wiring substrate. For example, a CSP (Chip Size Package) is known as a structure employing the flip-chip mounting.

With miniaturization and higher performance in electronic devices in recent years, demand has been ever greater for further miniaturization of semiconductor devices. With such miniaturization of semiconductor devices, it is of absolute necessity that the pitch of electrodes to enable mounting on the printed wiring board be made narrower. With this flip-chip method, however, there are restrictive factors for the narrowing of the pitch of electrodes, such as the size of the solder bump itself and the bridge formation at soldering. As one structure used to overcome these limitations, known is a structure where a bump structure formed on a wiring layer made of a metal such as copper (hereinafter this bump structure will be called “bump electrode”) is used as an electrode or a via. Also, in this known structure, the electrodes of the semiconductor device are connected to the bump electrodes by mounting the semiconductor device on a substrate with an insulating resin, such as epoxy resin, held between the semiconductor device and the substrate.

Where the connection is made to an electrode of the semiconductor using the conventional bump electrode, an insulating resin flows into a space between a top face of the bump electrode and the electrode and, consequently, part of the insulating resin may remain there as residues. As a result, a faulty electrical connection may occur.

### SUMMARY OF THE INVENTION

The present invention has been made in view of the foregoing circumstances, and a purpose thereof is to provide a device mounting board having bump electrodes capable of enhancing the connection reliability between the bump electrodes and the semiconductor device. Also, another purpose thereof is to provide a semiconductor module with an improved connection reliability between the bump electrodes and the semiconductor device and to provide a portable device equipped with such a semiconductor module.

One embodiment of the present invention relates to a device mounting board. The device mounting board comprises: a substrate; a wiring layer provided on the substrate; and a bump electrode, wherein a recess is provided in a top face of the bump electrode.

By employing the device mounting board according to this embodiment, when the device electrode and the bump electrode in the semiconductor device mounted on the device mounting board are joined together, the recess is filled with part of an insulating resin layer and therefore the insulating resin layer is less likely to remain as residues on a joint surface between the bump electrode and the device electrode. As a result, the connection reliability between the bump electrode and the device electrode is improved.

In the above-described embodiment, the recess may communicate with an opening provided on a side surface of the bump electrode. Also, the opening may be provided on the side surface of the bump electrode opposite to a direction along which the wiring layer extends, the wiring layer being connected to the bump electrode. Also, the recess may be provided in a central region of the top face of the bump electrode.

Another embodiment of the present invention relates to a semiconductor module. The semiconductor module comprises: a device mounting board according to the above-described embodiment; and a semiconductor device provided with a device electrode disposed counter to the bump electrode, wherein the bump electrode and the device electrode are electrically connected to each other.

By employing this embodiment, the connection reliability between the bump electrodes and the device electrodes is improved in the semiconductor module.

Still another embodiment of the present invention relates to a portable device. The portable device mounts a semiconductor module according to any of the above-described embodiments.

By employing this embodiment, the connection reliability between the bump electrodes and the device electrodes is improved in the portable device and therefore the operation reliability of the portable device is improved.

It is to be noted that any arbitrary combinations or rearrangement of the aforementioned structural components and so forth are all effective as and encompassed by the embodiments of the present invention.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a cross-sectional view showing a structure of a semiconductor module according to an embodiment of the present invention.

FIG. 2 is a plan view of a bump electrode on a top face side thereof.

FIG. 3 is a side view of a bump electrode.

FIGS. 4A to 4E are cross-sectional views showing a process in a method for forming a device mounting board and a semiconductor module according to an embodiment.

FIGS. 5A to 5F are cross-sectional views showing a process in a method for forming a device mounting board and a semiconductor module according to an embodiment.

FIG. 6 is a schematic plan view of a resist used in the formation of a bump electrode.

FIGS. 7A to 7D are first to fourth modifications, respectively, where a recess is provided in a top face.

FIG. 8A is a cross-sectional view of a model structure of a semiconductor module used for a simulation model.

FIG. 8B is a plan view showing an arrangement of a wiring layer, a bump electrode and a semiconductor device in a model structure of a semiconductor module.

FIG. 9A shows the shape and dimensions of a bump electrode used in a comparative example.

FIG. 9B shows the shape and dimensions of a bump electrode use in a first example embodiment and a second example embodiment.

FIGS. 10A and 10B show an equivalent stress distribution in a bump electrode of a comparative example and a Z-direction stress distribution in the bump electrode of the comparative example, respectively.

FIGS. 11A and 11B show an equivalent stress distribution in a bump electrode of a first example embodiment and a Z-direction stress distribution in the bump electrode of the first example embodiment, respectively.

FIGS. 12A and 12B show an equivalent stress distribution in a bump electrode of a second example embodiment and a Z-direction stress distribution in the bump electrode of the second example embodiment, respectively.

FIG. 13 illustrates a structure of a mobile phone provided with a semiconductor module according to an embodiment.

FIG. 14 is a partial cross-sectional view of the mobile phone shown in FIG. 13.

### DETAILED DESCRIPTION OF THE INVENTION

The invention will now be described by reference to the preferred embodiments. This does not intend to limit the scope of the present invention, but to exemplify the invention.

Hereinbelow, the embodiments will be described with reference to the accompanying drawings. Note that in all of the Figures the same reference numerals are given to the same components and the description thereof is omitted as appropriate.

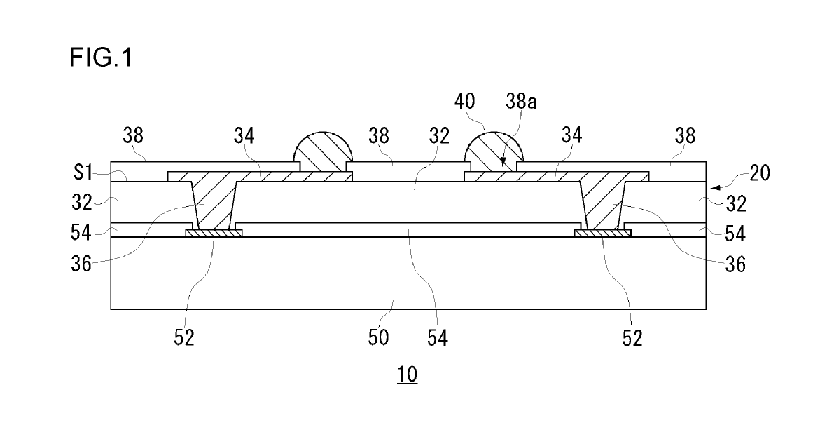

FIG. 1 is a cross-sectional view showing a structure of a semiconductor module according to an embodiment of the present invention. A device mounting board 20 includes an insulating resin layer 32, a wiring layer 34 provided on one of main surfaces, namely a main surface S1, of the insulating resin layer 32, and a bump electrode 36, electrically connected to the wiring layer 34, which is protruded (projected) from the wiring layer 34 toward an insulating resin layer 32 side. The semiconductor module 10 is formed by electrically connecting a semiconductor device 50 to this bump electrode 36.

The insulating resin layer 32 is made of an insulating resin, which may be an epoxy-based thermosetting resin, for instance.

The wiring layer 34 is provided on the main surface S1 of the insulating resin layer 32, and is formed of a conducive material, preferably a rolled metal or more preferably a rolled copper. Or the wiring layer 34 may be formed of electrolyte copper or the like. The bump electrode 36 is provided, in a protruding manner, on the insulating resin layer 32 side of the wiring layer 34. Although in the present embodiment the wiring layer 34 and the bump electrode 36 are formed integrally with each other, the structure is not particularly limited thereto. A protective layer 38 is provided on the other of the main surfaces, namely the other main surface, of the wiring layer 34 opposite to the insulating resin layer 32. This protective layer 38 protects the wiring layer 34 against oxidation or the like. The protective layer 38 may be a solder resist layer, for instance. An opening 38a is formed in a predetermined position of the protective layer 38, and the wiring layer 34 is partially exposed there. A solder part 40, which functions as an external connection electrode, is formed within the opening 38a. And the solder part 40 and the wiring layer 34 are electrically connected to each other. The position in which the solder part 40 is formed, namely, the area in which the opening 38a is formed is, for instance, a targeted position where circuit wiring is extended through a rewiring.

The overall shape of the bump electrode 36 may be narrower toward the tip portion thereof. In other words, the side surface of the bump electrode 36 may be tapered. Also, a metallic layer, such as a Ni/Au plating layer, may be provided on a top face of the bump electrode 36. The shape of the top face of the bump electrode 36 will be discussed later.

The semiconductor device 50 is an active element such as an integrated circuit (IC) or a large-scale integrated circuit (LSI) formed on a semiconductor substrate (e.g., Si substrate).

Device electrodes 52 are provided on a main surface of the semiconductor device 50 at an insulating resin layer 32 side and disposed counter to the bump electrodes 36, respectively. A protective layer 54 is provided on the main surface of the semiconductor element 40 at the insulating resin layer 32 side thereof. This protective layer 54 is provided so that the device electrodes 52 are exposed. For example, a polyimide may be used for the protective layer 54.

The semiconductor module 10 structured as above is mounted on a packaging board in such a manner that the solder parts 40, such as solder balls, are bonded to electrode pads provided on the packaging board, such as a printed circuit board.

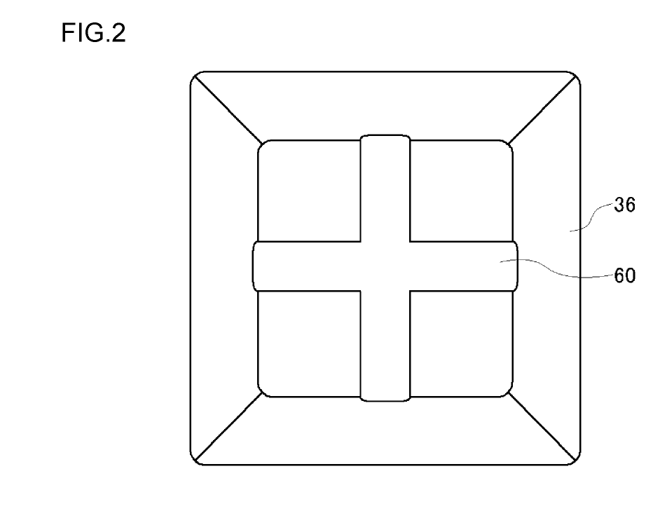

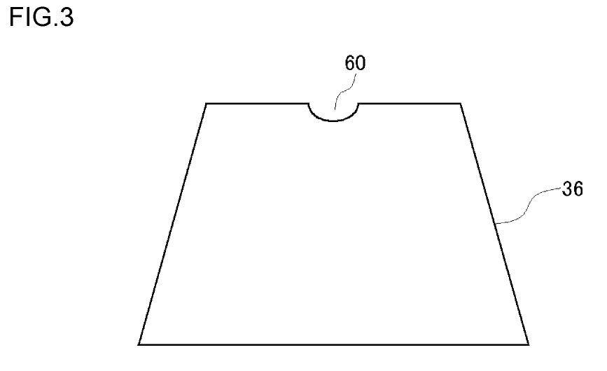

A description is now given of the shape of the top face of the bump electrode 36. FIG. 2 is a plan view of the bump electrode 36 on a top face side thereof. FIG. 3 is a side view of the bump electrode 36. In the present embodiment, the top face of the bump electrode 36 which is a surface in contact with the above-described device electrode 52 is rectangular in shape. The bump electrode 36 has a recess 60 in the top face thereof. In the present embodiment, the recess 60 is cruciate grooves; the grooves extend, in a criss-cross manner, to openings provided in side surfaces connecting to the sides of the top face. In other words, the recess 60 communicates with the openings provided on the side surfaces of the bump electrode 36.

When the bump electrode 36 and the device electrode 52 are bonded together, the recess 60 is filled with part of the aforementioned insulating resin layer 32 and therefore the insulating resin layer 32 is less likely to remain as residues on the joint surface between the bump electrode 36 and the device electrode 52. As a result, the connection reliability between the bump electrode 36 and the device electrode 52 is improved. In other words, when the bump electrode 36 and the device electrode 52 are to be joined together, the insulating resin layer 32 interposed therebetween can enter the recess 60. This helps prevent the insulating resin layer 32 from staying on the joint surface between the bump electrode 36 and the device electrode 52.

Also, the recess 60 communicates with the openings provided on the side surfaces of the bump electrode 36. Thus, if the amount of the insulating resin layer 32 is more than the amount which can fit into the recess 60 when the bump electrode 36 and the device electrode 52 are bonded together, the insulating resin layer 32 will be pushed out of the openings provided on the side surfaces of the bump electrode 36. This further helps prevent the insulating resin layer 32 from remaining on the joint surface between the bump electrode 36 and the device electrode 52.

A region in which the recess 60 is to be provided is not limited to any particular location but it is desirable that the region shall contain a central part of the top face of the bump electrode 36. Residues are likely to be occur in a central region of the top face of the bump electrode 36 if no recess 60 is provided. Thus, the provision of the recess 60 in a central region of the top face of the bump electrodes can effectively suppress the occurrence of residues.

The minimum number of openings to be provided on the side surfaces of the bump electrode is one. However, if the openings are provided equiangularly as viewed planarly from the top face of the bump electrode 36 (every 90 degrees in the present embodiment), an extra insulating resin layer 32 can be uniformly pushed out through each opening and consequently the occurrence of residues can be effectively suppressed. As a result, the adhesion between the bump electrode 36 and the device electrode 52 improves, thereby improving the connection reliability between the bump electrode 36 and the device electrode 52.

Also, the bump electrodes 36 may be arranged in a row along an outer periphery of the semiconductor module 10. In such a case, the recess 60 provided in the top face of the bump electrode 36 may face in a given direction in the bump electrodes arranged in a row along an outer periphery. Moreover, at least one of the open-ended openings of the recess 60 provided in the top face of the bump electrode 36 preferably faces the outer periphery of the semiconductor module 10.

(Method for Fabricating a Device Mounting Board and a Semiconductor Module.)

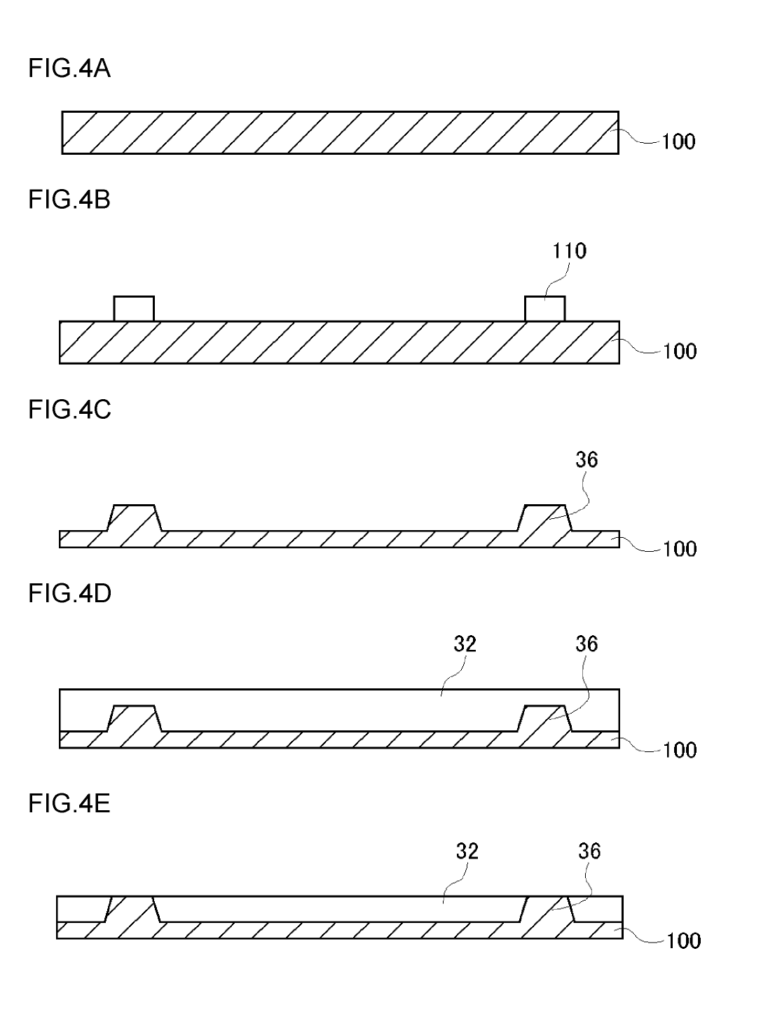

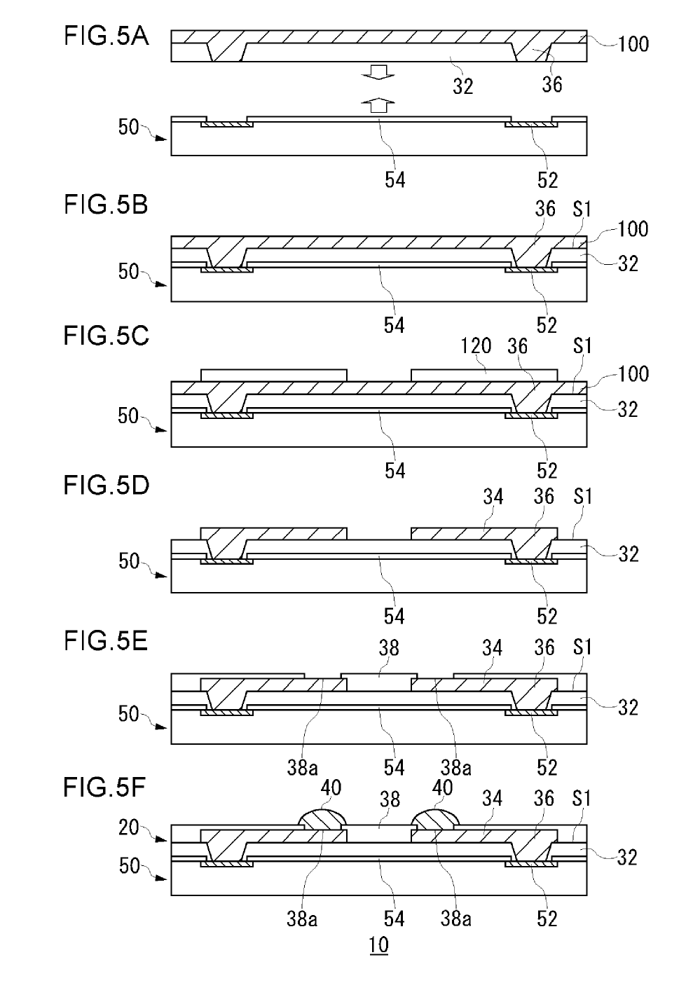

FIGS. 4A to 4E and FIG. 5A to 5F are cross-sectional views showing a process in a method for forming a device mounting board and a semiconductor module. Method for fabricating a semiconductor module.

As illustrated in FIG. 4A, a copper sheet 100 is first prepared as a metallic sheet having a thickness greater than at least the sum of the height of the bump electrode 36 and the thickness of the wiring layer 34.

Then, as illustrated in FIG. 4B, resists 110 are formed selectively in alignment with a pattern of bump electrodes 36 using a photolithography method. More specifically, a resist film of predetermined film thickness is affixed to the copper sheet 100 by a laminating apparatus, and it is then subjected to exposure by the use of a photo mask having the pattern of bump electrodes 36. After this, the resists 110 are selectively formed on the copper sheet 100 by a development. To improve the adhesion of the resists to the copper sheet 100, it is desirable that a pretreatment, such as grinding, cleaning and the like, be performed as necessary on the surface of the copper sheet 100 before the lamination of the resist film thereon.

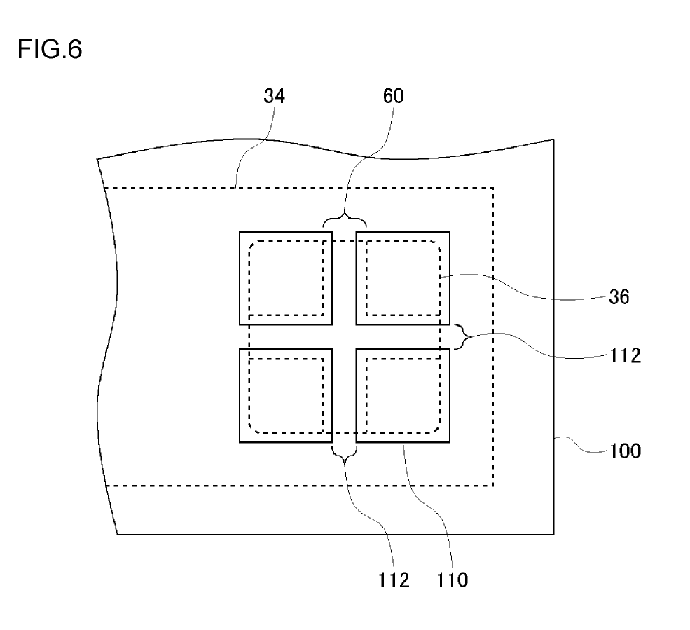

FIG. 6 is a schematic plan view of the resists 110 used in the formation of the bump electrode 36. As illustrated in FIG. 6, the resists 110 have slits 112 in alignment with the recesses 60 formed in the top face of the bump electrode 36. The slits 112 are so designed as to be narrower than the recesses 60 in anticipation of that a lower part of the resist 110 will be partially cut away by etching. with an upper part of the second bump electrode 70

Then, referring back to the explanation in conjunction with FIGS. 4A to 4E, as illustrated in FIG. 4C, the bump electrodes 36 having a predetermined pattern are formed on the copper sheet 100 using the resists 110 as a mask. More concretely, the bump electrodes 36 having a predetermined pattern are formed by etching the copper sheet 100 using the resists 110 as a mask. At this time, a not-shown recess is formed in the top face of the bump electrode 36 in accordance with a pattern of resist 110. After the formation of the bump electrodes 36, the resists 110 are removed using a remover. Thus the bump electrodes 36 are formed on the copper sheet 100 through a process as described above. The length of each side of a base, the length of each side of a top face, and the height of the bump electrode 36 are about 75 μmφ, about 60 μmφ, and about 30 μmφ, respectively.

Though, in the present embodiment, a recess is formed in the top face of the bump electrode 36 formed of copper, the recess may be formed in such a manner that a metallic layer, such as a Ni/Au plating layer, is formed in the top face of the bump electrode 36 and then this metallic layer is selectively removed. In this case, the exposed surface will become the top face of the bump electrode 36.

Then, as illustrated in FIG. 4D, an insulating resin layer 32 is stacked on the copper sheet 100 on a side where the bump electrodes 36 are formed, using a laminating apparatus.

Then, as illustrated in FIG. 4E, the insulating resin layer 32 is thinned by the use of O₂ plasma so etching so that the top face of the bump electrode 36 is exposed.

Then, as illustrated in FIG. 5A, the copper sheet 100 is positioned in such a manner that the top face of the bump electrode 36 faces the semiconductor device 50. At the same time, positioned is the semiconductor device 50 provided with the device electrodes 52, which are located opposite to the bump electrodes 36. Then, the copper sheet 100 and the semiconductor device 50 are press-bonded to each other using a press machine. The pressure and temperature to be employed in the press-forming are about 5 MPa and about 200° C., respectively.

At the time of the press-forming, the insulating resin layer 1012 develops a plastic flow with heat and under pressure. Then the insulating resin layer 32 flows into a space between the semiconductor device 50 and the copper sheet 100 to fit on the shape of the protective layer 54 having openings so that the device electrodes 52 can be exposed thereon. Then, as illustrated in FIG. 5B, the copper sheet 100, the insulating resin layer 32 and the semiconductor device 50 are integrated into a single block with the result that the bump electrodes 36 and the device electrodes 52 are press-bonded and thus electrically coupled with each other. When the bump electrodes 36 and the device electrodes 52 are bonded together, a part of the insulating resin layer 32 also flows into a space between the bump electrode 36 and the device electrode 52. However, in the present embodiment, the recess communicating with the openings provided on the side surfaces of the bump electrode 36 is provided in the top face of the bump electrode 36. This allows the insulating resin layer 32 interposed therebetween to enter the recess, which helps prevent the insulating resin layer 32 from staying on the joint surface between the bump electrode 36 and the device electrode 52. Also, if the amount of the insulating resin layer 32 is more than the amount which can fit into the recess 60, the insulating resin layer 32 will be pushed out of the openings provided on the side surfaces of the bump electrode 36. This further helps prevent the insulating resin layer 32 from remaining on the joint surface between the bump electrode 36 and the device electrode 52.

Then, as illustrated in FIG. 5C, resists 120 are formed selectively, in alignment with a pattern of wiring layer 34, on a main surface of the copper sheet 100 opposite to the insulating resin layer 32, using the lithography method.

Then, as illustrated in FIG. 5D, the wiring layer 34 having a predetermined pattern is formed in the copper sheet 100 by etching the main surface of the copper sheet 100 using the resists 120 as a mask. After that, the resists 120 are removed. The thickness of the wiring layer 34 according to the present embodiment is about 30 μm.

Then, as illustrated in FIG. 5E, a protective layer 38, which has openings 38a in regions corresponding to the positions for the formation of solder parts 40, is formed on the main surface of the wiring layer 34, which is on the side opposite to the insulating resin layer 32, using the lithography method.

Then, as illustrated in FIG. 5F, the solder parts 40 are formed within the openings 38a of the land area which is part of the wiring layer 34.

Thus, the semiconductor module 10 is formed through processes as described above. Or, where the semiconductor device 50 is not mounted, the device mounting board 20 is obtained.

(Modifications)

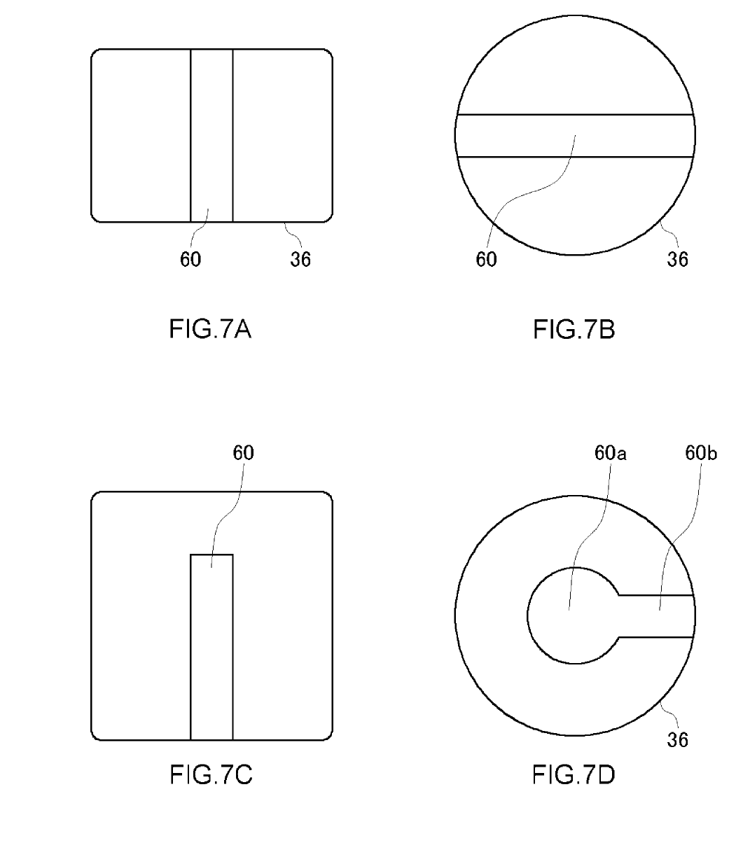

FIGS. 7A to 7D illustrate first to fourth modifications, respectively, of the bump electrode 36 where a recess is provided in the top face of the bump electrode 36. In the first modification and the second modification, the both ends of linear recess 60 communicate with openings provided on the side surfaces of the bump electrode 36, respectively. In the first modification, the top face of the bump electrode 36 is rectangular with the rounded corners; a pair of openings are provided on the side surfaces of the bump electrode 36 wherein one side surface of the bump electrode 36 is disposed counter to the other thereof. In the second modification, the top face of the bump electrode 36 is circular. In the third modification, one end of recess 60 provided in the top face of the bump electrode 36 communicates with an opening provided on a side surface of the bump electrode 36. The other end of recess 60 is terminated within the top face of the bump electrode 36; that is, the other end thereof is terminated without reaching a side surface of the bump electrode 36. In the fourth modification, there is provided a recess 60 including a first recess 60a and a second recess 60b. The first recess 60a, which is circular in shape, is provided in a central region of the top face of the bump electrode 36, whereas the second recess 60b, which is linear in shape, communicates with the circular first recess 60a. One end of a linear groove opposite to a circular groove communicates with an opening provided on the side surface of the bump electrode.

In each of the modifications described above, the structure where a groove communicating to an opening provided on a side surface of the bump electrode is provided on the top face of the bump electrode is the same as that of the above-described embodiment. Thus, the same advantageous effects as those of the embodiment can be achieved.

(Evaluation of Thermal Stress Applied to Bump Electrodes)

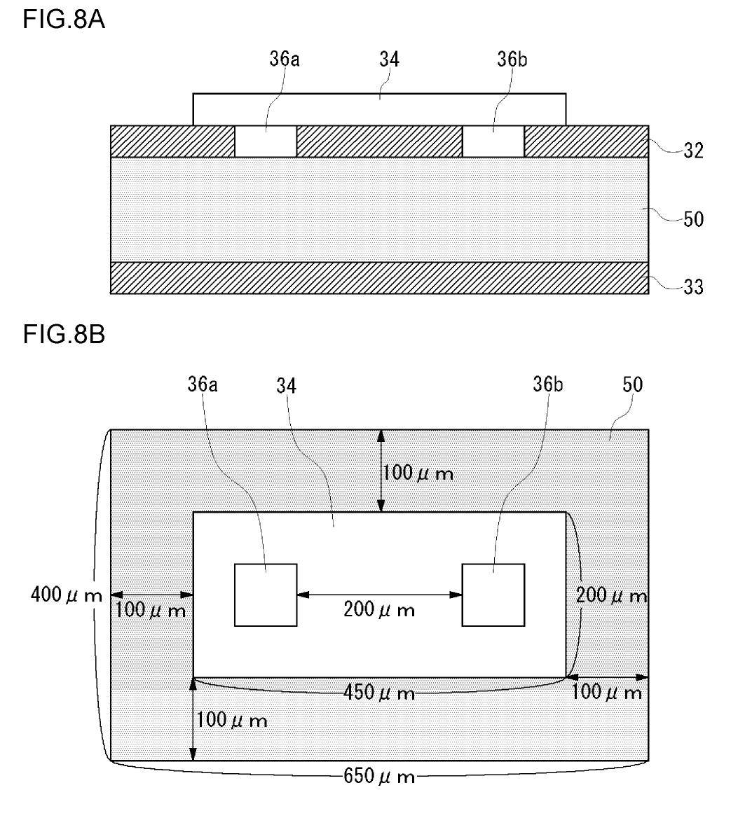

The thermal stress applied to a structure where grooves communicate with openings provided on the side surfaces of a bump electrode are provided in the top face of the bump electrode is evaluated through simulation runs using a finite-element method analysis software “ANSYS”. FIG. 8A is a cross-sectional view of a model structure of a semiconductor module used for a simulation model. FIG. 8B is a plan view showing an arrangement of rewiring, bump electrodes and a Si substrate in the model structure of a semiconductor module.

As illustrated in FIG. 8A, the model structure of a semiconductor module is such that bump electrodes 36a and 36b and a wiring layer (rewiring) 34 are integrally formed into a single block near both ends of the wiring layer 34 formed of Cu and the top faces of the bump electrodes 36a and 36b are in contact with a semiconductor device (Si substrate) 50. An insulating resin layer 32 fills a gap between the wiring layer 34 and the semiconductor device 50. The other surface of the semiconductor device 50 is covered with an insulating resin layer 33. The thickness of the semiconductor device 50, the wiring layer 34, the insulating layer 32 and the insulating layer 33 are 300 μm, 10 μm, 30 μm, and 30 μm, respectively. As illustrated in FIG. 8B, the dimensions of the semiconductor device 50 are 400 μm×650 μm, whereas the dimensions of the wiring layer 34 are 200 μm×450 μm. The spacing (interval) between the bump electrode 36a and the bump electrode 36b is 200 μm.

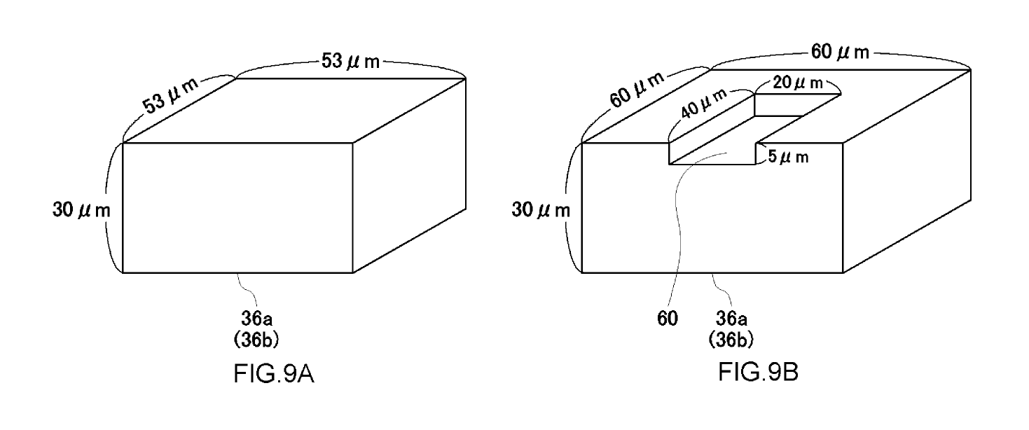

While the above-described model structure is set as a fundamental structure, a pair of bump electrodes 36a and 36b are shaped as shown FIG. 9A in a comparative example of a semiconductor module. As illustrated in FIG. 9A, no recess is provided in top faces of the bump electrodes 36a and 36b in the comparative example.

On the other hand, a pair of bump electrodes 36a and 36b are shaped as shown FIG. 9B in a first example embodiment of a semiconductor module. As illustrated in FIG. 9B, each top face of the bump electrodes 36a and 36b in the first example embodiment has a recess 60 where a side surface of each bump electrode is open-ended. The depth and the width of the recess 60 are 5 μm and 20 μm. In the first example embodiment, an open-ended opening of the recess 60 is provided on a side surface of each of the bump electrodes 36a and 36b which face each other. In other words, an open-ended opening of the recess 60 is formed on the side surface of the bump electrode 36a on a side where the wiring layer 34 being connected to the bump electrode 36a extends. Also, an open-ended opening of the recess 60 is formed on the side surface of the bump electrode 36b on a side where the wiring layer 34 being connected to the bump electrode 36b extends. In order to have an equal contact area with the semiconductor device in both the first example embodiment and the comparative example, the dimensions of the top face of the bump electrode 36 in the first example embodiment is 60 μm×60 μm, whereas the dimensions of the top face of the bump electrode 36 in the comparative example is 53 μm×53 μm.

In a semiconductor module according to a second example embodiment, the shape of a pair of bump electrodes 36a and 36b is the same as that of the first example embodiment, namely the structure where a recess 60 is provided in the top face; an open-ended opening of the recess is provided on a side surface opposed to the side surface of each of the bump electrodes 36a and 36b which face each other. In other words, an open-ended opening of the recess 60 is formed on the side surface (on an extreme-end side of the wiring layer 34) opposite to the side surface of the bump electrode 36a on a side where the wiring layer 34 being connected to the bump electrode 36a extends. Also, an open-ended opening of the recess 60 is formed on the side surface (on an extreme-end side of the wiring layer 34) opposite to the side surface of the bump electrode 36b on a side where the wiring layer 34 being connected to the bump electrode 36b extends.

Table 1 indicates the physical properties of materials used in the simulation runs.

TABLE 1

| | | | Linear | |
|---|---|---|---|---|
| | | | coefficient | |
| | Young's | | of | Glass |
| | modulus | Poisson's | expansion | transition |
| Material | [GPa] | ratio | α [ppm/K] | temperature |
| Cu | 130 | 0.35 | 17 | — |
| Si substrate | 190 | 0.3 | 3 | — |
| Insulating | 1.1 | 0.35 | 140 | 137 |
| resin | | | | |

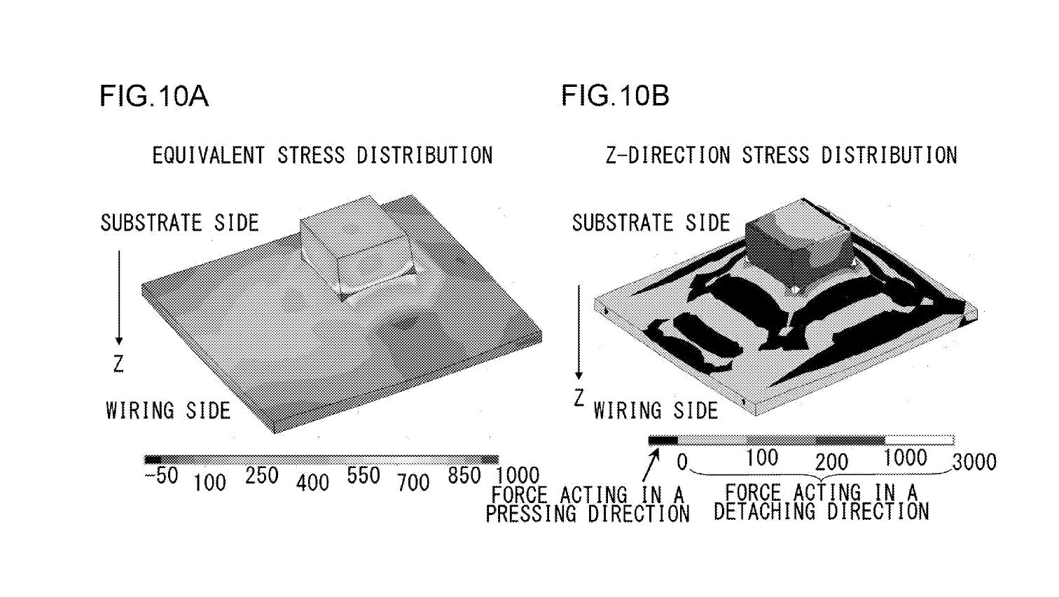

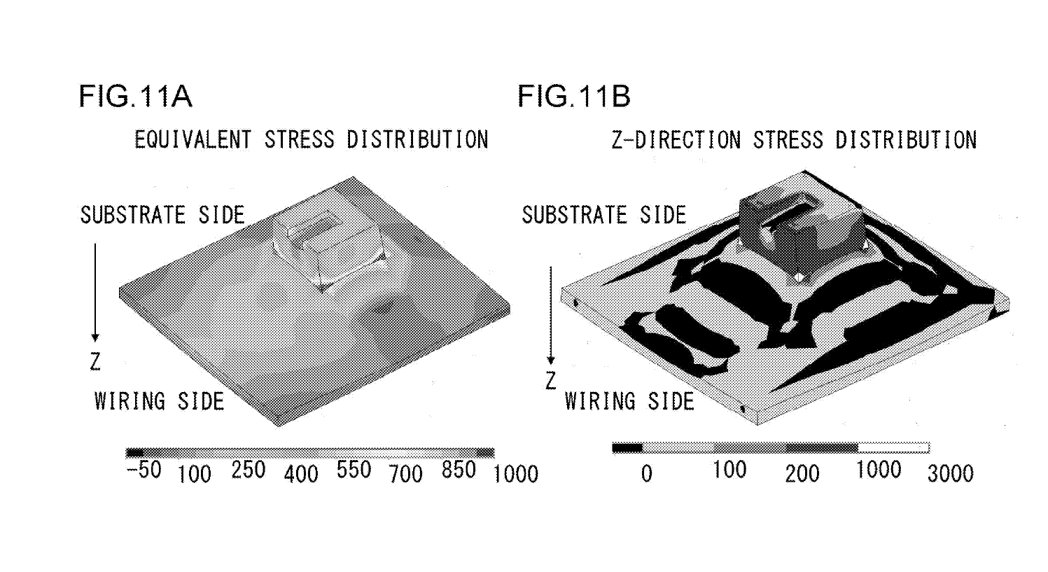

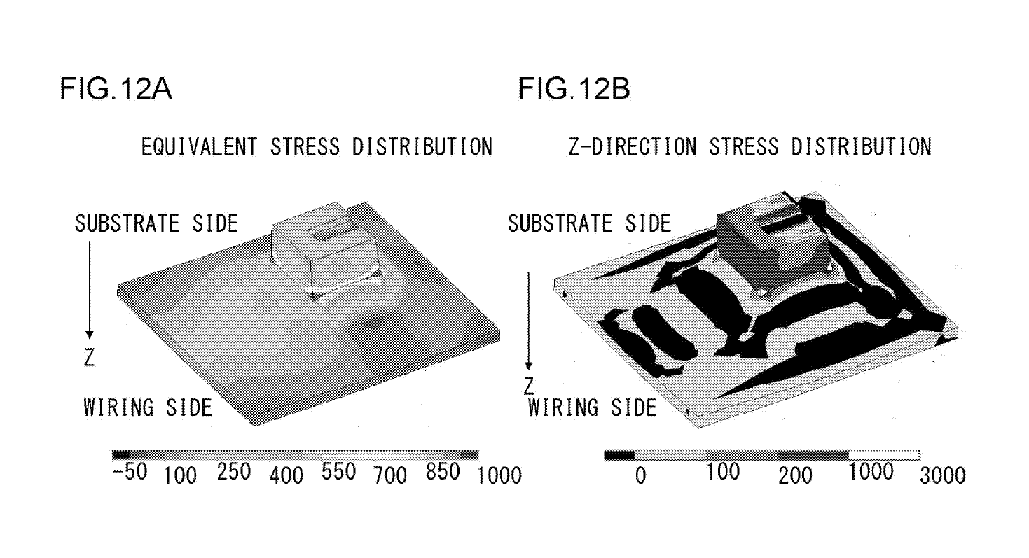

Assuming that the stress at a temperature of 25° C. is zero, a stress analysis in a temperature rising process in which the temperatures rises from 25° C. to 125° C. is conducted on the model structures of the semiconductor modules according to the comparative example, the first example embodiment and the second example embodiment, respectively. The bump electrodes 36a and 36 of the mode structure are arranged symmetrically relative to the wiring layer 34, so that the stress distribution arising therefrom is also symmetrical to each other. FIGS. 10A and 10B show an equivalent stress distribution in the bump electrode 36 of the comparative example and a Z-direction stress distribution in the bump electrode 36 of the comparative example, respectively. FIGS. 11A and 11B show an equivalent stress distribution in the bump electrode 36 of the first example embodiment and a Z-direction stress distribution in the bump electrode 36 of the first example embodiment, respectively. FIGS. 12A and 12B show an equivalent stress distribution in the bump electrode 36 of the second example embodiment and a Z-direction stress distribution in the bump electrode 36 of the second example embodiment, respectively. In each of FIGS. 10A to FIG. 12B, the bump electrode is drawn such that a semiconductor device 50 side is oriented along the negative direction of the Z axis and a wiring layer 34 side is oriented along the positive direction of the Z axis. In each of FIG. 10B, FIG. 11B and FIG. 12B, areas where the stress in the Z direction is positive indicates a force required to detach the bump electrode 36 from the semiconductor 50, whereas areas where the stress in the Z direction is negative indicates a force applied when the bump electrode 36 presses against the semiconductor device 50. The results of analysis conducted on the comparative example, the first example embodiment and the second example embodiment are shown in Table 2.

TABLE 2

| | | 1st | 2nd |
|---|---|---|---|
| | Comparative | example | example |
| | example | embodiment | embodiment |
| Max. equivalent stress | 3086 | 2914 | 2894 |
| Max. equivalent stress | — | 94.43% | 93.78% |
| ratio | | | |
| Max. Z-direction stress | 3335 | 3137 | 3126 |
| Max. Z-direction stress | — | 94.10% | 93.70% |
| ratio | | | |
| Min. Z-direction stress | −365 | −381 | −375 |
| Min. Z-direction stress | — | 104.40% | 102.70% |
| ratio | | | |

As illustrated in FIG. 10A, FIG. 11A and FIG. 12A, the maximum equivalent stress is applied to the base (a place at which the bump electrode connects to the rewiring) of the bump electrode. As illustrated in FIG. 10B, FIG. 11B and FIG. 12B, the maximum stress in the Z-direction stress is negative (a force in a direction where the bump electrode is pressed against the Si substrate) and is applied to a contact surface, between the bump electrode and the Si substrate, on a side far from the wiring, whereas the minimum stress is positive (a force in a direction where the bump electrode is detached from the Si substrate) and is applied to the base of the bump electrode. The maximum equivalent ratio of the maximum equivalent stress of the bump electrode 36 in the first example embodiment over the maximum equivalent stress of the bump electrode 36 in the comparative example is 94.43%. Thus, it is verified that the maximum equivalent stress of the bump electrode 36 in the first example embodiment is smaller than that of the bump electrode 36 in the comparative example. Also, the maximum Z-direction stress ratio of the maximum Z-direction stress of the bump electrode 36 in the first example embodiment over the maximum Z-direction stress of the bump electrode 36 in the comparative example is 94.13%. Also, the minimum Z-direction stress ratio of the minimum Z-direction stress of the bump electrode 36 in the first example embodiment over the minimum Z-direction stress of the bump electrode 36 in the comparative example is 104.40%.

As evident from above, it is verified that the stress applied to the base of the bump electrode 36, namely the maximum equivalent stress, tends to drop in the bump electrode 36 according to the first example embodiment. Also, it is verified that the stress in the direction where the bump electrode 36 is detached from the semiconductor device 50 decreases and the stress in the direction where the bump electrode 36 is pressed against the semiconductor device 50 increases. These results prove that the adhesion between the bump electrode 36 and the semiconductor device 50 in the first example embodiment improves.

It is verified that the tendency confirmed in the bump electrode 36 according to the first example embodiment becomes stronger in the second example embodiment. Thus, the adhesion between the bump electrode 36 and the semiconductor device 50 further improves in the second example embodiment. Thus, it is verified that a structure where the opening end is provided on the side surface of the bump electrode opposite to the direction along which the wiring layer connecting to the bump electrode 36 extends is more desirable.

Next, a description will be given of a mobile apparatus (portable device) provided with a semiconductor module according to an embodiment. The mobile apparatus, which incorporating the semiconductor module, presented as an example herein is a mobile phone, but it may be any electronic apparatus, such as a personal digital assistant (PDA), a digital video cameras (DVC) or a digital still camera (DSC).

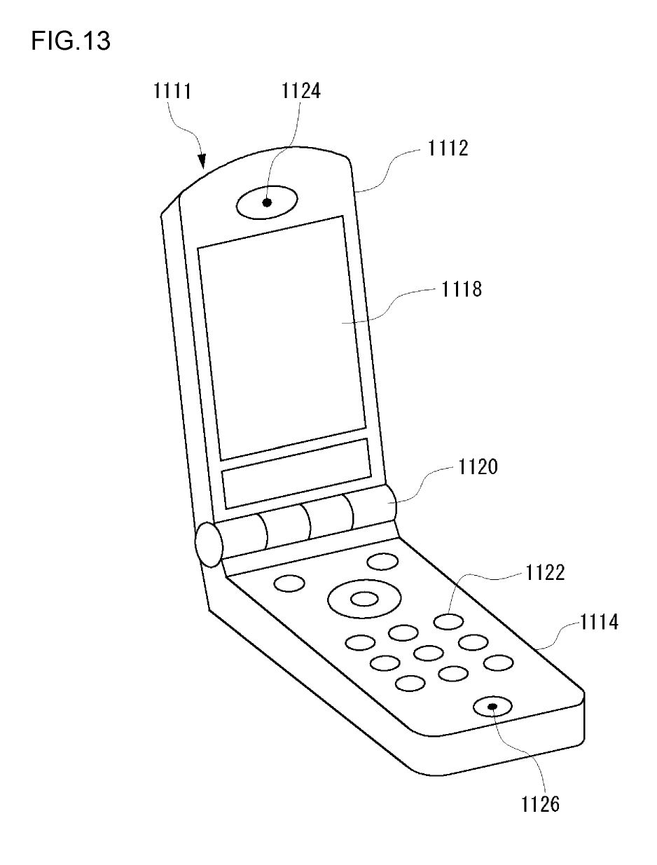

FIG. 13 illustrates a structure of a mobile phone provided with a semiconductor module 10 according to each of the above-described embodiments of the present invention. A mobile phone 1111 has a basic structure of a first casing 1112 and a second casing 1114 jointed together by a movable part 1120. The first casing 1112 and the second casing 1114 are turnable around the movable part 1120 as the axis. The first casing 1112 is provided with a display unit 1118 for displaying characters, images and other information and a speaker unit 1124. The second casing 1114 is provided with a control module 1122 with operation buttons and a microphone 1126. Note that a semiconductor module 100 according to the above-described embodiment and its modification is mounted within a mobile phone 1111 such as this. The semiconductor module, according to the above-described embodiment and its modification, mounted on a mobile phone may be used for a power supply circuit used to drive each circuit, an RF generation circuit for generating RF, a digital-to-analog converter (DAC), an encoder circuit, a driver circuit for a backlight used as the light source of a liquid-crystal panel used for a display of the mobile phone, and the like.

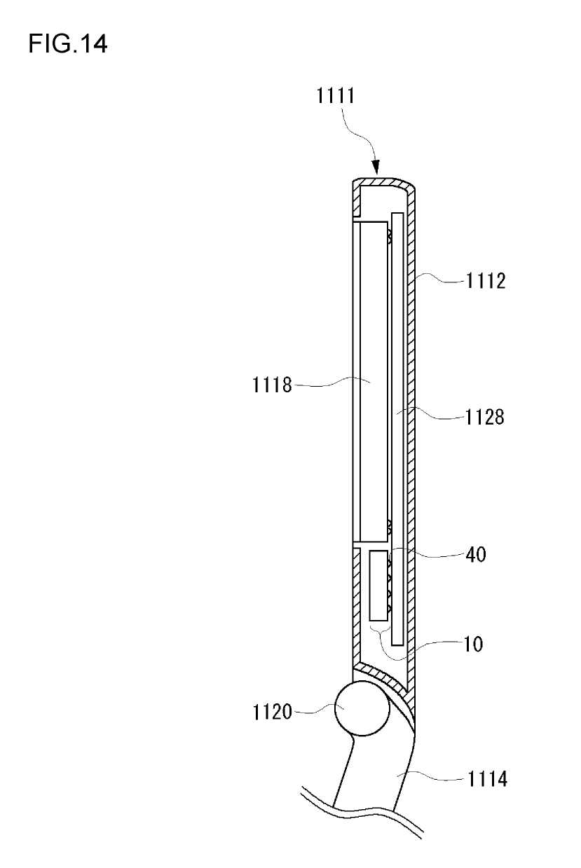

FIG. 14 is a partial cross-sectional view (cross-sectional view of the first casing 1112) of the mobile phone shown in FIG. 13. The semiconductor module 10 according to the present embodiment is mounted on a printed circuit board 1128 via the solder bumps 40 and is coupled electrically to the display unit 1118 and the like by way of the printed circuit board 1128.

By employing the mobile apparatus provided with a semiconductor module according to the above-described embodiment of the present invention, the following advantageous effects can be achieved.

The connection reliability between the semiconductor device and the bump electrodes improve in the semiconductor module 10 according to the above-described embodiment and modification, thereby improving the operation reliability of the mobile device incorporating such the semiconductor module 10.

The present invention has been described by referring to the above-described embodiment and modification. However, the present invention is not limited to the above-described embodiments only. It is understood that various modifications such as changes in design may be further made based on the knowledge of those skilled in the art, and the embodiments added with such modifications are also within the scope of the present invention.

What is claimed is:

1. A device mounting board, comprising:
a substrate;
a wiring layer provided on said substrate; and
a bump electrode,
wherein a recess is provided in a top face of said bump electrode.

2. A device mounting board according to claim 1, wherein the recess communicates with an opening provided on a side surface of said bump electrode.

3. A device mounting board according to claim 2, wherein the opening is provided on the side surface of said bump electrode opposite to a direction along which said wiring layer extends, said wiring layer being connected to said bump electrode.

4. A device mounting board according to claim 1, wherein the recess is provided in a central region of the top face of said bump electrode.

5. A semiconductor module, comprising:
a device mounting board according to claim 1; and
a semiconductor device provided with a device electrode disposed counter to said bump electrode,
wherein said bump electrode and the device electrode are electrically connected to each other.
